(19) United States
(12) Patent Application Publication
(10) Pub. No.: US 2026/0281755 A1
(43) Pub. Date: Sep. 17, 2026

(54) WIRELESS MEASUREMENT DEVICE AND WIRELESS MEASUREMENT METHOD

(71) Applicant: ANRITSU CORPORATION, Kanagawa (JP)

(72) Inventors: Takaaki KAMISAWA, Kanagawa (JP); Hirofumi KANNO, Kanagawa (JP); Yoshiya SHIKAMA, Kanagawa (JP)

(21) Appl. No.: 19/562,914

(22) Filed: Mar. 11, 2026

(30) Foreign Application Priority Data
Mar. 14, 2025 (JP) 2025-041505

(51) Int. Cl. H04W 24/06; H03M 1/12; H04B 17/15

(52) U.S. Cl. CPC H04W 24/06; H03M 1/12; H04B 17/15

(57) ABSTRACT

In a signal analysis device, a transmission signal attenuated by a set attenuation amount is downconverted into an IF signal, and then subjected to AD conversion. In a first baseband converter and a second baseband converter, a signal after the AD conversion is multiplied by a local signal of sin θ and a local signal of cos θ, and baseband signals of an I component and a Q component whose unnecessary spectra are removed are respectively output. A first decoder performs decoding processing on the output signal into IQ data, and a second decoder performs decoding processing on the output signal into IQ data. The cross correlation EVM calculation unit calculates error vectors from the two pieces of IQ data, performs a cross correlation EVM calculation, and performs average processing on results of the cross correlation EVM calculation to calculate a cross correlation EVM.

### TECHNICAL FIELD

The present invention relates to a wireless measurement device and a wireless measurement method that receive a transmission signal from a device under test (DUT) and perform measurement.

### BACKGROUND ART

Recent developments in communication require an increase in signal bandwidth and an increase in modulation order. For example, in a WLAN standard IEEE 802.11be, there is a demand for a signal bandwidth of 160 MHz to 320 MHz and a modulation method of 256 QAM to 1024 QAM and 4096 QAM, and EVM requirements are stricter as the modulation order increases.

Further, in 4096 QAM of the next-generation WLAN standard IEEE 802.11be, an EVM is set to -38 dB. In the above case, a sufficient margin is required for highly reliable measurement, and a residual EVM of -53 to -55 dB is expected as performance required for a signal source and a spectrum analyzer.

As a method of measuring such high-accuracy EVM, a method of calculating cross correlation EVM is a very effective method. In a cross correlation EVM algorithm, high-accuracy EVM measurement of the signal source is achieved by using a technique in which floor noise of a measuring instrument is received in two channels and EVM is calculated using two error vectors to cancel uncorrelated noise.

Patent Document 1 discloses a measurement system that splits a measurement signal from a DUT into two parts and calculates phase noise.

### Related art Document

### Patent Document

Patent Document 1 JP-A-2019-158418

### DISCLOSURE OF THE INVENTION

### Problem that the Invention is to Solve

However, two signal analysis devices are required in order to perform the split of the measurement signal from the DUT into two parts as in Patent Document 1 and the calculation of an actual cross correlation EVM using two error vectors.

The present invention has been made in view of the above problems, and an object of the present invention is to provide a wireless measurement device and a wireless measurement method capable of calculating a cross correlation EVM with one signal analysis device.

### Means for solving the problem

In order to achieve the above object, a wireless measurement device according to claim 1 of the present invention is a wireless measurement device 1 including:
a signal analysis device 2 that receives a transmission signal S generated by a signal generation device W as a device under test and performs signal analysis; and
a cross correlation EVM calculation unit 3 that calculates a cross correlation EVM based on an analysis result of the signal analysis device,
in which the signal analysis device includes
an attenuator 11 that attenuates the transmission signal by an attenuation amount set in advance,
a down converter 12 that downconverts a signal attenuated by the attenuator into a signal of an intermediate frequency,
an AD converter 13 that performs AD conversion on the signal downconverted by the down converter,
a first baseband converter 14 that multiplies a signal subjected to the AD conversion by the AD converter by a first local signal of cos θ and outputs a signal of an I component whose unnecessary spectrum is removed, and multiplies a signal subjected to the AD conversion by a first local signal of sin θ and outputs a signal of a Q component whose unnecessary spectrum is removed,
a second baseband converter 15 that multiplies a signal subjected to the AD conversion by a second local signal of cos θ and outputs a signal of an I component whose unnecessary spectrum is removed, and multiplies a signal subjected to the AD conversion by a second local signal of sin θ and outputs a signal of a Q component whose unnecessary spectrum is removed,
a first decoder 16 that performs decoding processing on the signal output from the first baseband converter into IQ data, and
a second decoder 17 that performs decoding processing on the signal output from the second baseband converter into IQ data, and the cross correlation EVM calculation unit calculates error vectors from the IQ data of the first decoder, performs a cross correlation EVM calculation using the calculated error vectors, and performs average processing on results of the cross correlation EVM calculation to calculate a cross correlation EVM.

The wireless measurement device according to claim 2 of the present invention is the wireless measurement device according to claim 1,
in which a plurality of the down converters 12 are connected in series between the attenuator 11 and the AD converter 13.

The wireless measurement device according to claim 3 of the present invention is the wireless measurement device according to claim 1, the wireless measurement device further including:
a setting unit 4 that sets the number of samples, an input level range, and an attenuation change amount of the transmission signal S, as a first measurement condition 21; and
a display unit 5 that displays a graph showing the cross correlation EVM, which is calculated by the cross correlation EVM calculation unit 3 in a case where the first measurement condition is set, and the input level,
in which an appropriate input level is selected from the graph showing the cross correlation EVM and the input level.

The wireless measurement device according to claim 4 of the present invention is the wireless measurement device according to claim 3,
in which the cross correlation EVM calculation unit 3 calculates a cross correlation EVM in a case where the setting unit 4 sets the input level, which is selected from the graph showing the relationship between the cross correlation EVM and the input level, and a range of the number of samples, as a second measurement condition 22,
the display unit 5 displays a graph showing the cross correlation EVM, which is calculated by the cross correlation EVM calculation unit in a case where the second measurement condition is set, and the number of samples, and
a final EVM value is calculated from the graph showing the EVM and the number of samples.

The wireless measurement method according to claim 5 of the present invention is a wireless measurement method in which a signal analysis device receives a transmission signal S generated by a signal generation device W as a device under test and performs signal analysis, and a cross correlation EVM calculation unit 3 calculates a cross correlation EVM based on an analysis result of the signal analysis device, the wireless measurement method including:
a step of attenuating the transmission signal by an attenuation amount set in advance, by an attenuator 11 of the signal analysis device;
a step of downconverting a signal attenuated by the attenuator into a signal of an intermediate frequency, by a down converter 12 of the signal analysis device;
a step of performing AD conversion on the signal downconverted by the down converter, by an AD converter 13 of the signal analysis device;
a step of multiplying a signal subjected to the AD conversion by the AD converter by a local signal of cos θ and outputting a signal of an I component whose unnecessary spectrum is removed, and multiplying a signal subjected to the AD conversion by a local signal of sin θ and outputting a signal of a Q component whose unnecessary spectrum is removed, by a first baseband converter 14 of the signal analysis device;
a step of multiplying a signal subjected to the AD conversion by a local signal of cos θ and outputting a signal of an I component whose unnecessary spectrum is removed, and multiplying a signal subjected to the AD conversion by a local signal of sin θ and outputting a signal of a Q component whose unnecessary spectrum is removed, by a second baseband converter 15 of the signal analysis device;
a step of performing decoding processing on a signal including first floor noise N1, which is downconverted to a signal of an intermediate frequency by the first baseband converter, into IQ data, by a first decoder 16 of the signal analysis device;
a step of performing decoding processing on a signal including second floor noise N2, which is downconverted to a signal of an intermediate frequency by the second baseband converter, into IQ data, by a second decoder 17 of the signal analysis device; and
a step of calculating error vectors from the IQ data of the first decoder and the IQ data of the second decoder, performing a cross correlation EVM calculation using the calculated error vectors, and performing average processing on results of the cross correlation EVM calculation to calculate a cross correlation EVM.

The wireless measurement method according to claim 6 of the present invention is the wireless measurement method according to claim 5, the wireless measurement method further including:
a step of connecting a plurality of the down converters 12 in series between the attenuator 11 and the AD converter 13.

The wireless measurement method according to claim 7 of the present invention is the wireless measurement method according to claim 5, the wireless measurement method further including:
a step of setting the number of samples, an input level range, and an input level measurement step of the transmission signal S, as a first measurement condition 21;
a step of displaying a graph showing a relationship between the cross correlation EVM, which is calculated in a case where the first measurement condition is set, and the input level; and
a step of selecting an appropriate input level from the graph showing the relationship between the cross correlation EVM and the input level.

The wireless measurement method according to claim 8 of the present invention is the wireless measurement method according to claim 7, the wireless measurement method further including:
a step of calculating a cross correlation EVM in a case where the input level, which is selected from the graph showing the relationship between the cross correlation EVM and the input level, and a range of the number of samples are set, as a second measurement condition 22;
a step of displaying a graph showing a relationship between the cross correlation EVM, which is calculated in a case where the second measurement condition is set, and the number of samples; and
a step of calculating a final EVM value from the graph showing the relationship between the cross correlation EVM and the number of samples.

### Advantage of the Invention

According to the present invention, the cross correlation EVM calculation can be performed with one signal analysis device, and since the error of the split signal path is small, as compared with a case where two signal analysis devices are used, more accurate measurement is possible.

### BRIEF DESCRIPTION OF THE DRAWINGS

FIG. 1 is a block diagram showing a schematic configuration of a wireless measurement device according to a first embodiment of the present invention.

FIG. 2 is a block diagram showing a schematic configuration of a wireless measurement device according to a second embodiment of the present invention.

FIG. 3 is a diagram showing a display example of a first measurement condition and a first measurement result in the wireless measurement device according to the present invention.

FIG. 4 is a diagram showing a display example of a second measurement condition and a second measurement result in the wireless measurement device according to the present invention.

FIG. 5 is a flowchart showing a schematic operation of a measurement method using the wireless measurement device according to the present invention.

### BEST MODE FOR CARRYING OUT THE INVENTION

Hereinafter, embodiments of the present invention will be described in detail with reference to accompanying drawings.

### Regarding Overview of Present Invention

In the present invention, cross correlation EVM calculation is performed with one signal analysis device. In the present embodiment, a case where one down converter (with a mixer inside) is used and a case where two down converters (down converter + mixer) are used will be described as examples.

### First Embodiment

A wireless measurement device of a first embodiment is a measurement system in a case where one down converter is used in the signal analysis device to perform the cross correlation EVM calculation with one signal analysis device.

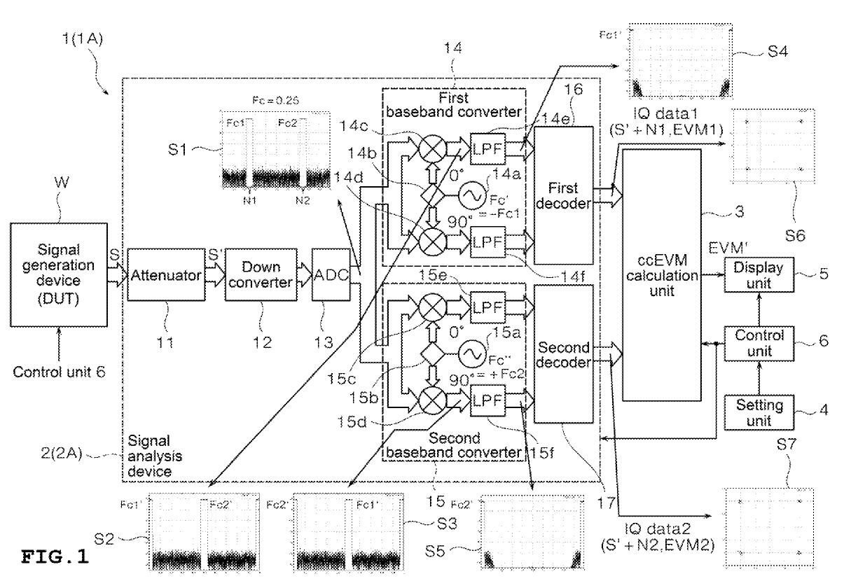

As shown in FIG. 1, a wireless measurement device 1 (1A) of the first embodiment is schematically configured to include one signal analysis device 2 (2A), a cross correlation EVM calculation unit 3, a setting unit 4, a display unit 5, and a control unit 6.

As shown in FIG. 1, one signal analysis device 2A is connected to a signal generation device W as a device under test (DUT) and receives a transmission signal S generated by the signal generation device W to perform signal analysis, and is configured to include an attenuator 11, a down converter 12, an AD converter (denoted as ADC in FIG. 1) 13, a first baseband converter 14, a second baseband converter 15, a first decoder 16, and a second decoder 17.

The attenuator 11 attenuates the transmission signal S from the signal generation device W by an attenuation amount set by the setting unit 4, and inputs an attenuated signal S' to the down converter 12.

The down converter 12 is configured of an analog mixer and an analog filter (low-pass filter), and downconverts the signal S' attenuated by the attenuator 11 into a signal (IF signal) having a predetermined intermediate frequency (IF) using the analog mixer, deletes one half of the downconverted IF signal using the analog filter, and inputs the signal to the AD converter 13.

In a case where an expression (Fs = 1.0) normalized at a sampling rate (Fs Hz) of the AD converter 13 is used as a specific numerical example, since the sampling rate is normalized at Fs = 1, in a case where a normalized value is replaced with an actual frequency, the actual frequency can be calculated by multiplying the normalized value by an actual value of the sampling rate. For example, in a case where Fs’ = 1 GHz, Fc = 0.25 × 1 GHz = 250 MHz.

The AD converter 13 performs AD conversion on the signal from the down converter 12, and inputs the signal subjected to the AD conversion to the first baseband converter 14 and the second baseband converter 15. As shown in S1 of FIG. 1, signals Fc1 and Fc2 after the AD conversion are one-channel spectra that are left-right symmetric. Further, SN of the signal is determined by floor noise (first floor noise N1 and second floor noise N2) immediately before the AD conversion.

For example, in S1 of FIG. 1, in a case where the intermediate frequency is 1 GHz, a frequency of the down converter 12 is -975 MHz, and the sampling rate of the AD converter 13 is 100 MHz, the intermediate frequency after the down conversion is 1 GHz - 975 MHz = 25 MHz. In a case where normalization is performed at the sampling rate of 100 MHz (Fs = 1.0), Fc1 = 25 MHz/100 MHz = 0.25, and Fc2 = 1 - 0.25 = 0.75.

The actual sampling rate is basically determined by a bandwidth of a target signal. For example, in a case where Fs’ = 100 MHz, the AD conversion can be performed on a signal having a bandwidth of up to 50 MHz in maximum.

The first baseband converter 14 is configured to include a local oscillator 14a, a local signal generation unit 14b, a cosine-side mixer 14c, a sine-side mixer 14d, a cosine-side low-pass filter unit 14e, and a sine-side low-pass filter unit 14f.

In the first baseband converter 14, the local oscillator 14a generates a phase signal θ, and the local signal generation unit 14b generates local signals of sin θ and cos θ from the phase signal θ. The cosine-side mixer 14c multiplies the local signal of cos θ by the input signals Fc1 and Fc2 (signals after AD conversion), and the cosine-side low-pass filter unit 14e inputs, to the first decoder 16, baseband signals of an I component and a Q component (complex signals) (signals shown in S4 in FIG. 1) whose unnecessary spectra are removed from the multiplied signals (signals shown in S2 in FIG. 1). Further, the sine-side mixer 14d multiplies the local signal of sin θ by the input signals Fc1 and Fc2 (signals after AD conversion), and the sine-side low-pass filter unit 14f inputs, to the first decoder 16, baseband signals of an I component and a Q component (complex signals) (signals shown in S5 in FIG. 1) whose unnecessary spectra are removed from the multiplied signals (signals shown in S3 in FIG. 1).

The second baseband converter 15 is configured to include a local oscillator 15a, a local signal generation unit 15b, a cosine-side mixer 15c, a sine-side mixer 15d, a cosine-side low-pass filter unit 15e, and a sine-side low-pass filter unit 15f, as in the first baseband converter 14.

In the second baseband converter 15, the local oscillator 15a generates a phase signal θ, and the local signal generation unit 15b generates local signals of sin θ and cos θ from the phase signal θ. The cosine-side mixer 15c multiplies the local signal of cos θ by the input signals Fc1 and Fc2 (signals after AD conversion), and the cosine-side low-pass filter unit 15e inputs, to the second decoder 17, baseband signals of an I component and a Q component (complex signals) (signals shown in S4 in FIG. 1) whose unnecessary spectra are removed from the multiplied signals (signals shown in S2 in FIG. 1). Further, the sine-side mixer 15d multiplies the local signal of sin θ by the input signals Fc1 and Fc2 (signals after AD conversion), and the sine-side low-pass filter unit 15f inputs, to the second decoder 17, baseband signals of an I component and a Q component (complex signals) (signals shown in S5 in FIG. 1) whose unnecessary spectra are removed from the multiplied signals (signals shown in S3 in FIG. 1).

The first decoder 16 performs decoding processing on a signal S’+N1 including the first floor noise N1 downconverted into the signal (IF signal) of the intermediate frequency by the first baseband converter 14, and inputs IQ data (constellation data): IQdata1 (S’+N1, EVM1) shown in S6 of FIG. 1 to the cross correlation EVM calculation unit 3.

The second decoder 17 performs decoding processing on a signal S’+N2 including the second floor noise N2 downconverted into the signal (IF signal) of the intermediate frequency by the second baseband converter 15, and inputs IQ data (constellation data): IQdata2 (S’+N2, EVM2) shown in S7 of FIG. 1 to the cross correlation EVM calculation unit 3.

The cross correlation EVM calculation unit 3 calculates the cross correlation EVM based on an analysis result of the signal analysis device 2A under the control of the control unit 6 based on the setting of the setting unit 4. The cross correlation EVM calculation unit 3 calculates error vectors from the IQ data of the first decoder 16 shown in S6 of FIG. 1 and the IQ data of the second decoder 17 shown in S7 of FIG. 1, performs a well-known cross correlation EVM calculation using the error vectors, and performs averaging processing on results of the cross correlation EVM calculation to calculate the EVM (EVM’).

The error vector is obtained by subtracting a reference signal (ideal signal) from an IQ vector as constellation data.

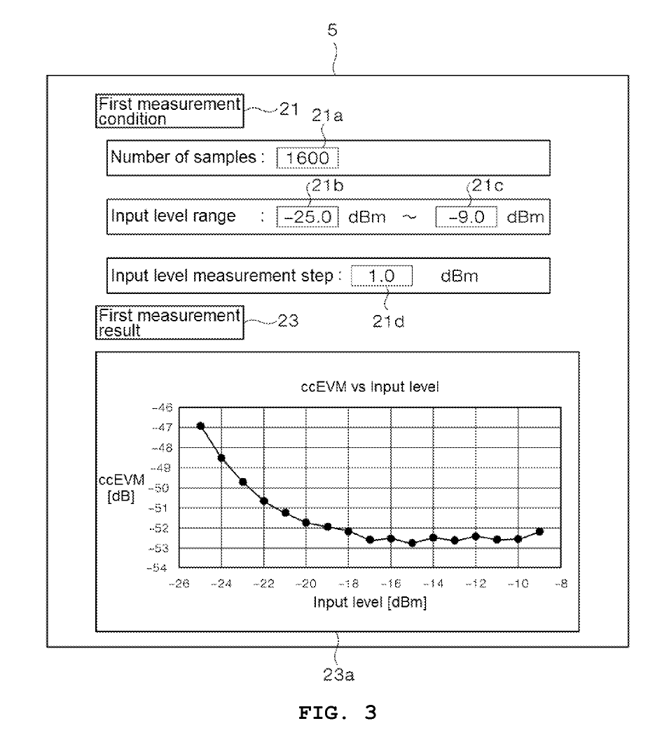

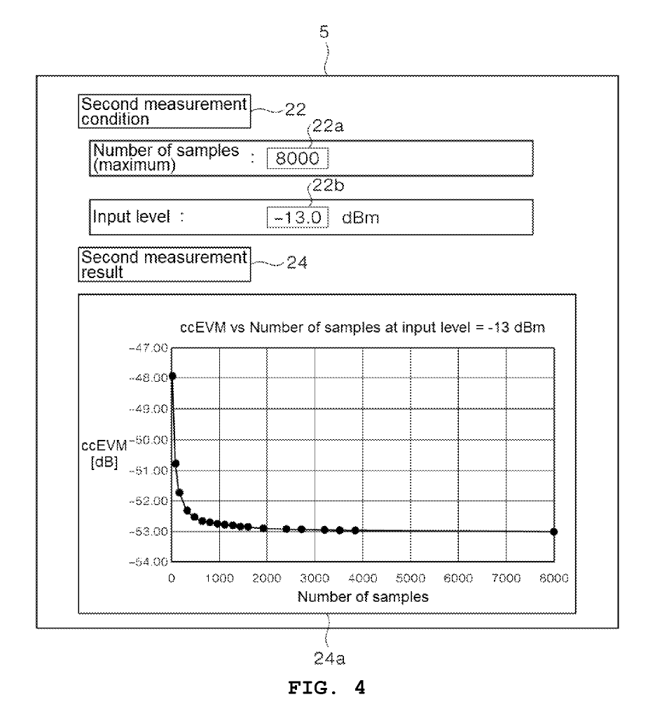

The setting unit 4 performs setting related to the signal analysis device 2A, setting related to the cross correlation EVM calculation unit 3, setting related to graph displays of FIGS. 3 and 4, and the like.

More specifically, the setting related to the signal analysis device 2A includes a signal input level, a frequency, the number of repeated acquisitions, and parameters of modulation analysis, and the like. In the setting related to the signal analysis device 2A, for example, in a case where a graph of the cross correlation EVM with changed input levels of FIG. 3 is obtained, the settings of the signal generation device W and the attenuator 11 need to be changed each time the input level is changed. Further, in a case where the measurement is performed, various parameters, such as the frequency or level, the number of parameters of the modulation signal, and the number of repeated acquisitions, in the signal generation device W, the attenuator 11, the first decoder 16, and the second decoder 17 also need to be set. Thus, detailed items will not be described here, and parameters, which are generally set in a case where the modulation analysis is performed, are referred to as the parameters of the modulation analysis.

The setting related to the cross correlation EVM calculation unit 3 includes the number of samples and input data specification setting. The input data specification setting includes a file name, the number of input samples, the number of symbols, and the number of subcarriers. The file name is for files output from the first decoder 16 and the second decoder 17 in a case where the cross correlation EVM is calculated at a measurement start, under general test conditions of a predetermined input level (for example, -25 dBm), a predetermined number of samples (for example, 1600), signal conditions (modulation waveform specifications such as modulation waveform: QPSK, format xx, number of subcarriers xx, and number of symbols xx), and the frequency or input level, and is calculated with the measurement of the input level at an input level measurement step (for example, -1.0 dBm), and a calculation result of the cross correlation EVM for each input level (result of each point) is acquired. The number of input samples is the number of samples displayed in the graphs of FIGS. 3 and 4 as the number of repetitions. In a case where an output text is output, for example, as the number of subcarriers (1 to 1000) × the number of symbols (1 to 16) and 16000 lines of text, the number of symbols and the number of subcarriers are used for processing such that the symbols (1000) are used for vector averaging, which is for averaging for cross correlation EVM, and then a cross correlation EVM value obtained after the vector averaging is averaged by the number of symbols (16). In this case, since the subcarrier and the symbol are separately used for calculation, information such as the number of subcarriers and the number of symbols is required.

The setting related to the graph display of FIG. 3 includes the calculation result of the cross correlation EVM for each input level (result of each point), the number of samples (for measurement condition display), a range of the cross correlation EVM (for Y-axis display), and the input level (display range of X-axis).

The setting related to the graph display in FIG. 4 includes the calculation result of the cross correlation EVM for each of the number of samples (result of each point), the number of samples (display range of X-axis), the range of the cross correlation EVM (for Y-axis display), and the input level (for measurement condition display).

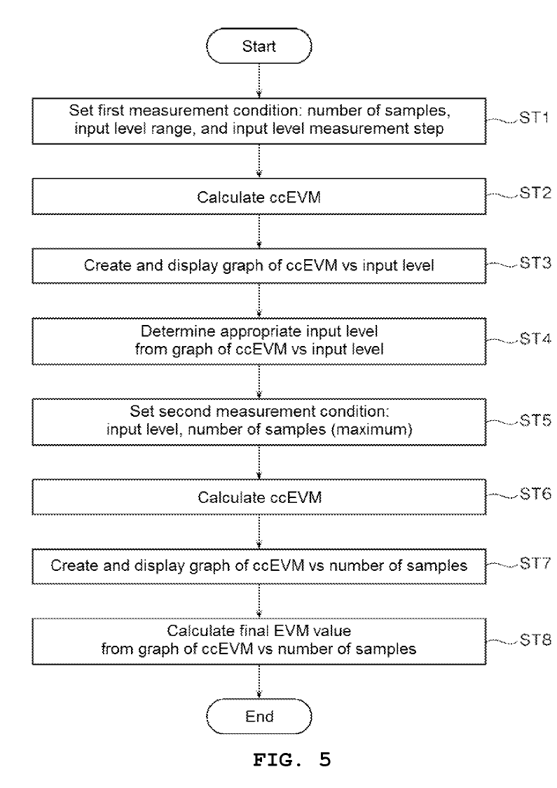

The display unit 5 is configured of, for example, a liquid crystal display (LCD) or an organic EL display (OLED), and displays, under the control of the control unit 6, a setting content by the setting unit 4, the calculation result by the cross correlation EVM calculation unit 3, measurement conditions (first measurement condition 21 in FIG. 3 and second measurement condition 22 in FIG. 4) and measurement results (first measurement result 23 in FIG. 3 and second measurement result 24 in FIG. 4) in a case where measurement is performed according to a procedure of a flowchart of FIG. 5 described below, and the like.

The number of samples of the transmission signal S acquired from the signal generation device W, the input level range (range of attenuation amount of the attenuator 11), and the input level measurement step (attenuation change amount of input level in the attenuator 11) are set as the first measurement condition 21.

As a specific example of the first measurement condition 21, for example, as shown in FIG. 3, “1600” is input and set in an input box 21a for the number of samples, “-25.0" (dBm) is input and set in an input box 21b for a lower limit value of the input level range, “-9.0" (dBm) is input and set in an input box 21c for an upper limit value of the input level range, and “1.0" (dBm) is input and set in an input box 21d for the input level measurement step.

Further, a selected appropriate input level and the number of samples (maximum) of the transmission signal S acquired from the signal generation device W are set as the second measurement condition 22.

As a specific example of the second measurement condition 22, for example, as shown in FIG. 4, “8000” is input and set in an input box 22a for the number of samples (maximum), and “-13.0” (dBm) is input and set in an input box 22b for the input level.

The control unit 6 is configured of, for example, a central processing unit (CPU), a read only memory (ROM), a random access memory (RAM), and the like, and integrally controls each unit (the signal analysis device 2A, the cross correlation EVM calculation unit 3, the setting unit 4, the display unit 5, and the signal generation device W) in order to perform the measurement in accordance with the procedure of the flowchart of FIG. 5 described below.

In the wireless measurement device 1A of the first embodiment configured as described above, the noise (first floor noise N1 and second floor noise N2) generated from the down converter 12 is added to the signals at Fc1 (LSB) and Fc2 (USB) as the signals after the down conversion, as shown in S1 of FIG. 1, but the wireless measurement device 1A is configured to delete uncorrelated floor noise by the cross correlation calculation, using the fact that the noise components N1 and N2 of Fc1 (LSB) and Fc2 (USB) are uncorrelated.

In general, only one of the LSB and USB signals is used, and an unused signal is perceived as a nuisance. However, an unused signal is also effectively used in the method of the present embodiment.

### Second Embodiment

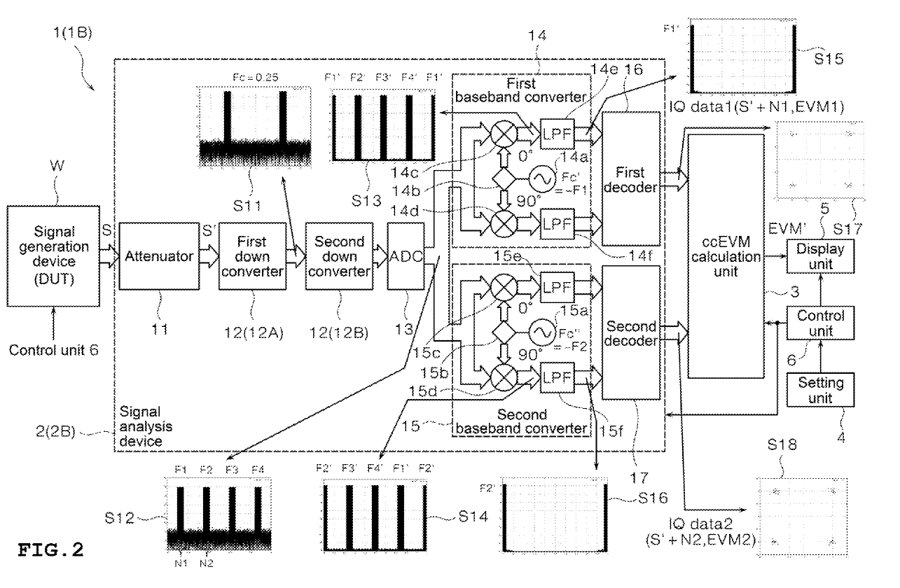

Next, a configuration of a wireless measurement device of a second embodiment will be described with reference to FIG. 2. In FIG. 2, the same reference numerals are assigned to the same components as those of the wireless measurement device 1A of the first embodiment of FIG. 1.

As shown in FIG. 2, a wireless measurement device 1 (1B) of the second embodiment is schematically configured to include one signal analysis device 2 (2B), a cross correlation EVM calculation unit 3, a setting unit 4, a display unit 5, and a control unit 6, and is a measurement system in a case where two down converters are used in the signal analysis device 2B to perform the cross correlation EVM calculation with one signal analysis device 2B.

As shown in FIG. 2, one signal analysis device 2B is connected to a signal generation device W as a device under test (DUT) and receives a transmission signal S generated by the signal generation device W to perform signal analysis, and is configured to include an attenuator 11, a first down converter 12A (12), a second down converter 12B (12), an AD converter (denoted as ADC in FIG. 1) 13, a first baseband converter 14, a second baseband converter 15, a first decoder 16, and a second decoder 17.

The attenuator 11 attenuates the transmission signal S from the signal generation device W by an attenuation amount set by the setting unit 4, and inputs an attenuated signal S' to the second down converter 12B.

The first down converter 12A (12) has the same configuration as the down converter 12 of the wireless measurement device 1A of the first embodiment, and is configured of an analog mixer and an analog filter (low-pass filter). As shown in S11 of FIG. 2, the first down converter 12A (12) downconverts the signal S' attenuated by the attenuator 11 into a signal (IF signal) having a predetermined intermediate frequency (IF) using the analog mixer, deletes one half of the downconverted IF signal using the analog filter, and inputs the signal to the second down converter 12B.

In a case where an expression (Fs = 1.0) normalized at a sampling rate (Fs Hz) of the AD converter 13 is used as a specific numerical example, since the sampling rate is normalized at Fs = 1, in a case where a normalized value is replaced with an actual frequency, the actual frequency can be calculated by multiplying the normalized value by an actual value of the sampling rate. For example, in a case where Fs’ = 1 GHz, Fc = 0.25 × 1 GHz = 250 MHz.

The second down converter 12B (12) is configured of a mixer, and shifts the frequencies of the four signals F1, F2, F3, and F4 from the first down converter 12A and inputs the signals to the AD converter 13. For example, in a case where Fc = 0.25, F1 = 0.25 - 0.125 = 0.125, F2 = 0.25 + 0.125 = 0.375, F3 = 0.75 - 0.125 = 0.625, and F4 = 0.75 + 0.125 = 0.875. The SN is determined by the floor noise (first floor noise N1 and second floor noise N2) after the output of the second down converter 12B.

The AD converter 13 performs AD conversion on the signal from the second down converter 12B, and inputs the signal subjected to the AD conversion to the first baseband converter 14 and the second baseband converter 15. As shown in S12 of FIG. 2, signals F1, F2, F3, and F4 after the AD conversion are one-channel spectra that are left-right symmetric. Further, SN of the signal is determined by floor noise (first floor noise N1 and second floor noise N2) immediately before the AD conversion.

The first baseband converter 14 is configured to include a local oscillator 14a, a local signal generation unit 14b, a cosine-side mixer 14c, a sine-side mixer 14d, a cosine-side low-pass filter unit 14e, and a sine-side low-pass filter unit 14f.

In the first baseband converter 14, the local oscillator 14a generates a phase signal θ, and the local signal generation unit 14b generates local signals of sin θ and cos θ from the phase signal θ. The cosine-side mixer 14c multiplies the local signal of cos θ by the input signals F1, F2, F3, and F4 (signals after AD conversion), and the cosine-side low-pass filter unit 14e inputs, to the first decoder 16, baseband signals of an I component and a Q component (complex signals) (signals shown in S15 in FIG. 2) whose unnecessary spectra are removed from the multiplied signals (signals shown in S13 in FIG. 2). Further, the sine-side mixer 14d multiplies the local signal of sin θ and the input signals F1, F2, F3, and F4 (signals after AD conversion), and the sine-side low-pass filter unit 14f inputs, to the first decoder 16, baseband signals of an I component and a Q component (complex signals) (signals shown in S16 in FIG. 2) whose unnecessary spectra are removed from the multiplied signals (signals shown in S14 in FIG. 2).

The second baseband converter 15 is configured to include a local oscillator 15a, a local signal generation unit 15b, a cosine-side mixer 15c, a sine-side mixer 15d, a cosine-side low-pass filter unit 15e, and a sine-side low-pass filter unit 15f, as in the first baseband converter 14.

In the second baseband converter 15, the local oscillator 15a generates a phase signal θ, and the local signal generation unit 15b generates local signals of sin θ and cos θ from the phase signal θ. The cosine-side mixer 15c multiplies the local signal of cos θ by the input signals F1, F2, F3, and F4 (signals after AD conversion), and the cosine-side low-pass filter unit 15e inputs, to the second decoder 17, baseband signals of an I component and a Q component (complex signals) (signals shown in S15 of FIG. 2) whose unnecessary spectra are removed from the multiplied signals (signals shown in S13 of FIG. 2). Further, the sine-side mixer 15d multiplies the local signal of sin θ by the input signals F1, F2, F3, and F4 (signals after AD conversion), and the sine-side low-pass filter unit 15f inputs, to the second decoder 17, baseband signals of an I component and a Q component (complex signals) (signals shown in S16 of FIG. 2) whose unnecessary spectra are removed from the multiplied signals (signals shown in S14 of FIG. 2).

The first decoder 16 performs decoding processing on a signal S’+N1 including the first floor noise N1 downconverted into the signal (IF signal) of the intermediate frequency by the first baseband converter 14, and inputs IQ data (constellation data): IQdata1 (S’+N1, EVM1) shown in S17 of FIG. 2 to the cross correlation EVM calculation unit 3.

The second decoder 17 performs decoding processing on a signal S’+N2 including the second floor noise N2 downconverted into the signal (IF signal) of the intermediate frequency by the second baseband converter 15, and inputs IQ data (constellation data): IQdata2 (S’+N2, EVM2) shown in S18 of FIG. 2 to the cross correlation EVM calculation unit 3.

The cross correlation EVM calculation unit 3 calculates the cross correlation EVM based on an analysis result of the signal analysis device 2B under the control of the control unit 6 based on the setting of the setting unit 4. The cross correlation EVM calculation unit 3 calculates error vectors from the IQ data of the first decoder 16 shown in S17 of FIG. 2 and the IQ data of the second decoder 17 shown in S18 of FIG. 2, performs a well-known cross correlation EVM calculation using the error vectors, and performs averaging processing on results of the cross correlation EVM calculation to calculate the cross correlation EVM (EVM’).

The setting unit 4 performs setting related to the signal analysis device 2B, setting related to the cross correlation EVM calculation unit 3, setting related to graph displays of FIGS. 3 and 4, and the like.

More specifically, the setting related to the signal analysis device 2B includes a signal input level, a frequency, the number of repeated acquisitions, and parameters of modulation analysis, and the like. In the setting related to the signal analysis device 2B, for example, in a case where a graph of the cross correlation EVM with changed input levels of FIG. 3 is obtained, the settings of the signal generation device W and the attenuator 11 need to be changed each time the input level is changed. Further, in a case where the measurement is performed, various parameters, such as the frequency or level, the number of parameters of the modulation signal, and the number of repeated acquisitions, in the signal generation device W, the attenuator 11, the first decoder 16, and the second decoder 17 also need to be set. Thus, detailed items will not be described here, and parameters, which are generally set in a case where the modulation analysis is performed, are referred to as the parameters of the modulation analysis.

The setting related to the cross correlation EVM calculation unit 3 includes the number of samples and input data specification setting. The input data specification setting includes a file name, the number of input samples, the number of symbols, and the number of subcarriers. The file name is for files output from the first decoder 16 and the second decoder 17 in a case where the cross correlation EVM is calculated at a measurement start, under general test conditions of a predetermined input level (for example, -25 dBm), a predetermined number of samples (for example, 1600), signal conditions (modulation waveform specifications such as modulation waveform: QPSK, format xx, number of subcarriers xx, and number of symbols xx), and the frequency or input level, and is calculated with the measurement of the input level at an input level measurement step (for example, -2.0 dBm), and a calculation result of the cross correlation EVM for each input level (result of each point) is acquired. The number of input samples is the number of samples displayed in the graphs of FIGS. 3 and 4 as the number of repetitions. In a case where an output text is output, for example, as the number of subcarriers (1 to 1000) × the number of symbols (1 to 16) and 16000 lines of text, the number of symbols and the number of subcarriers are used for processing such that the symbols (1000) are used for vector averaging, which is for averaging for cross correlation EVM, and then a cross correlation EVM value obtained after the vector averaging is averaged by the number of symbols (16). In this case, since the subcarrier and the symbol are separately used for calculation, information such as the number of subcarriers and the number of symbols is required.

The setting related to the graph display of FIG. 3 includes the calculation result of the cross correlation EVM for each input level (result of each point), the number of samples (for measurement condition display), a range of the cross correlation EVM (for Y-axis display), and the input level (display range of X-axis).

The setting related to the graph display in FIG. 4 includes the calculation result of the cross correlation EVM for each of the number of samples (result of each point), the number of samples (display range of X-axis), the range of the cross correlation EVM (for Y-axis display), and the input level (for measurement condition display).

The display unit 5 is configured of, for example, a liquid crystal display (LCD) or an organic EL display (OLED), and displays, under the control of the control unit 6, a setting content by the setting unit 4, the calculation result by the cross correlation EVM calculation unit 3, measurement conditions (first measurement condition 21 and second measurement condition 22) and measurement results in a case where the measurement is performed according to the procedure of the flowchart of FIG. 5 described below, and the like.

The number of samples of the transmission signal S acquired from the signal generation device W, the input level range (range of attenuation amount of the attenuator 11), and the input level measurement step (variable attenuation amount of input level in the attenuator 11) are set as the first measurement condition 21.

As a specific example of the first measurement condition 21, for example, as shown in FIG. 3, “1600” is input and set in an input box 21a for the number of samples, “-25.0" (dBm) is input and set in an input box 21b for a lower limit value of the input level range, “-9.0" (dBm) is input and set in an input box 21c for an upper limit value of the input level range, and “1.0" (dBm) is input and set in an input box 21d for the input level measurement step.

Further, a selected appropriate input level and the number of samples (maximum) of the transmission signal S acquired from the signal generation device W are set as the second measurement condition 22.

As a specific example of the second measurement condition 22, for example, as shown in FIG. 4, “8000” is input and set in an input box 22a for the number of samples (maximum), and “-13.0” (dBm) is input and set in an input box 22b for the input level.

The control unit 6 is configured of, for example, a central processing unit (CPU), a read only memory (ROM), a random access memory (RAM), and the like, and integrally controls each unit (the signal analysis device 2B, the cross correlation EVM calculation unit 3, the setting unit 4, the display unit 5, and the signal generation device W) in order to perform the measurement in accordance with the procedure of the flowchart of FIG. 5 described below.

In the wireless measurement device 1B of the second embodiment configured as described above, the noise (first floor noise N1 and second floor noise N2) generated from the first down converter 12A is added to the signals at F1 and F2 as the signals after the down conversion, as shown in S12 of FIG. 2, but the wireless measurement device 1B is configured to delete uncorrelated floor noise by the cross correlation calculation, using the fact that the noise components N1 and N2 are uncorrelated.

In general, only the decoded signal is used, and an unused signal is perceived as a nuisance. However, a signal that is not usually used is also effectively used in the method of the present embodiment.

Next, a method of calculating the cross correlation EVM using the wireless measurement device 1A of the first embodiment or the wireless measurement device 1B of the second embodiment will be described with reference to the flowchart of FIG. 5.

First, the setting unit 4 sets, as the first measurement condition 21, the number of samples, the input level range, and the input level measurement step of the transmission signal S of the signal generation device (DUT) (ST1). For example, the number of samples: 1600, the input level range: -25 dBm to -9.0 dBm, and the input level measurement step: 1.0 dBm are input and set, as the first measurement condition 21, as shown in FIG. 3.

Next, the measurement is performed under the first measurement condition 21 set by the setting unit 4, and the cross correlation EVM is calculated (ST2).

A graph of cross correlation EVM (vertical axis) vs input level (horizontal axis) is created based on the calculated cross correlation EVM and the input level range of the first measurement condition 21, and the created graph of cross correlation EVM vs input level is displayed on the display unit 5 as the first measurement result 23 (ST3). Specifically, in a case where the number of samples: 1600, the input level range: -25 dBm to -9.0 dBm, and the input level measurement step: 1.0 dBm are set as the first measurement condition 21, a graph 23a of cross correlation EVM vs input level shown in FIG. 3 is displayed on the display unit 5 as the first measurement result 23.

Next, the graph of cross correlation EVM vs input level is checked, and an appropriate input level is determined (ST4).

Subsequently, in order to determine the input level of a final test in which the number of samples is increased and to perform measurement, the setting unit 4 sets the appropriate input level, which is determined from the graph of cross correlation EVM vs input level (for example, graph 23a of cross correlation EVM vs input level of the first measurement result 23 in FIG. 3), and the number of samples (maximum), as the second measurement condition 22 (ST5). For example, the number of samples (maximum): 8000 and the input level: -13.0 dBm are input and set, as the second measurement condition 22, as shown in FIG. 4.

Next, the measurement is performed under the second measurement condition 22 set by the setting unit 4, and the cross correlation EVM is calculated (ST6).

A graph of cross correlation EVM (vertical axis) vs number of samples (horizontal axis) is created based on the calculated cross correlation EVM and the number of samples of the second measurement condition 22, and the created graph of cross correlation EVM vs number of samples is displayed on the display unit 7 as the second measurement result 24 (ST7). Specifically, in a case where the number of samples (maximum): 8000 and the input level: -13.0 dBm are set as the second measurement condition 22, a graph 24a of cross correlation EVM vs number of samples shown in FIG. 4 is displayed on the display unit 7 as the second measurement result 24.

Next, check is made whether or not the number of samples is sufficient (whether or not the cross correlation EVM value has converged) from the graph of cross correlation EVM vs number of samples, and a final EVM value is calculated (ST8).

Incidentally, the wireless measurement device 1A of the first embodiment is described as having the configuration in which one down converter 12 is provided between the attenuator 11 and the AD converter 13 of the signal analysis device 2A, and the wireless measurement device 1B of the second embodiment is described as having the configuration in which two down converters 12 (first down converter 12A and second down converter 12B) are provided between the attenuator 11 and the AD converter 13 of the signal analysis device 2B, but the present invention is not limited thereto. That is, the number of down converters between the attenuator 11 and the AD converter 13 is not limited to one or two, and three or more downconverters may be connected in series as necessary to downconvert the signal S' after the attenuation into the signal (IF signal) of the intermediate frequency in a plurality of stages.

As described above, according to the present embodiment, the cross correlation EVM calculation can be performed with one signal analysis device. Accordingly, the error of the split signal path is small, as compared with a case where two signal analysis devices are used, and more accurate measurement is possible.

The best embodiments of the wireless measurement device and the wireless measurement method according to the present invention have been described above, but the present invention is not limited to the description and the drawings according to the embodiments. That is, it goes without saying that other modes, embodiments, and operational techniques implemented by those skilled in the art based on this mode are all included within the scope of the present invention.

### DESCRIPTION OF REFERENCE NUMERALS AND SIGNS

1 (1A, 1B): wireless measurement device

2 (2A, 2B): signal analysis device

3: cross correlation EVM calculation unit

4: setting unit

5: display unit

6: control unit

11: attenuator

12: down converter

12A (12): first down converter

12B (12): second down converter

13: AD converter

14: first baseband converter

14a: local oscillator

14b: local signal generation unit

14c: cosine-side mixer

14d: sine-side mixer

14e: cosine-side low-pass filter unit

14f: sine-side low-pass filter unit

15: second baseband converter

16: first decoder

17: second decoder

21: first measurement condition

21a: input box for number of samples

21b: input box for lower limit value of input level range

21c: input box for upper limit value of input level range

21d: input box for input level measurement step

22: second measurement condition

22a: input box for number of samples (maximum)

22b: input box for input level

23: first measurement result

23a: graph of cross correlation EVM vs input level

24: second measurement result

24a: graph of cross correlation EVM vs number of samples

W: signal generation device (DUT)

What is claimed is:

1. A wireless measurement device comprising:
a signal analysis device that receives a transmission signal generated by a signal generation device as a device under test and performs signal analysis; and
a cross correlation EVM calculation unit that calculates a cross correlation EVM based on an analysis result of the signal analysis device,
wherein the signal analysis device includes
an attenuator that attenuates the transmission signal by an attenuation amount set in advance,
a down converter that downconverts a signal attenuated by the attenuator into a signal of an intermediate frequency,
an AD converter that performs AD conversion on the signal downconverted by the down converter,
a first baseband converter that multiplies a signal subjected to the AD conversion by the AD converter by a first local signal of cos θ and outputs a signal of an I component whose unnecessary spectrum is removed, and multiplies a signal subjected to the AD conversion by a first local signal of sin θ and outputs a signal of a Q component whose unnecessary spectrum is removed,
a second baseband converter that multiplies a signal subjected to the AD conversion by a second local signal of cos θ and outputs a signal of an I component whose unnecessary spectrum is removed, and multiplies a signal subjected to the AD conversion by a second local signal of sin θ and outputs a signal of a Q component whose unnecessary spectrum is removed,
a first decoder that performs decoding processing on the signal output from the first baseband converter into IQ data, and
a second decoder that performs decoding processing on the signal output from the second baseband converter into IQ data, and
the cross correlation EVM calculation unit calculates error vectors from the IQ data of the first decoder and the IQ data of the second decoder, performs a cross correlation EVM calculation using the calculated error vectors, and performs average processing on results of the cross correlation EVM calculation to calculate a cross correlation EVM.

2. The wireless measurement device according to claim 1,
wherein a plurality of the down converters are connected in series between the attenuator and the AD converter.

3. The wireless measurement device according to claim 1, further comprising:
a setting unit that sets the number of samples, an input level range, and an attenuation change amount of the transmission signal, as a first measurement condition; and
a display unit that displays a graph showing the cross correlation EVM, which is calculated by the cross correlation EVM calculation unit in a case where the first measurement condition is set, and the input level,
wherein an appropriate input level is selected from the graph showing the cross correlation EVM and the input level.

4. The wireless measurement device according to claim 3,
wherein the cross correlation EVM calculation unit calculates a cross correlation EVM in a case where the setting unit sets the input level, which is selected from the graph showing the relationship between the cross correlation EVM and the input level, and a range of the number of samples, as a second measurement condition,
the display unit displays a graph showing the cross correlation EVM, which is calculated by the cross correlation EVM calculation unit in a case where the second measurement condition is set, and the number of samples, and
a final EVM value is calculated from the graph showing the EVM and the number of samples.

5. A wireless measurement method in which a signal analysis device receives a transmission signal generated by a signal generation device as a device under test and performs signal analysis, and a cross correlation EVM calculation unit calculates a cross correlation EVM based on an analysis result of the signal analysis device, the wireless measurement method comprising:
a step of attenuating the transmission signal by an attenuation amount set in advance, by an attenuator of the signal analysis device;
a step of downconverting a signal attenuated by the attenuator into a signal of an intermediate frequency, by a down converter of the signal analysis device;
a step of performing AD conversion on the signal downconverted by the down converter, by an AD converter of the signal analysis device;
a step of multiplying a signal subjected to the AD conversion by a local signal of cos θ and outputting a signal of an I component whose unnecessary spectrum is removed, and multiplying a signal subjected to the AD conversion by a local signal of sin θ and outputting a signal of a Q component whose unnecessary spectrum is removed, by a first baseband converter of the signal analysis device;
a step of multiplying a signal subjected to the AD conversion by a local signal of cos θ and outputting a signal of an I component whose unnecessary spectrum is removed, and multiplying a signal subjected to the AD conversion by a local signal of sin θ and outputting a signal of a Q component whose unnecessary spectrum is removed, by a second baseband converter of the signal analysis device;
a step of performing decoding processing on a signal including first floor noise, which is downconverted to a signal of an intermediate frequency by the first baseband converter, into IQ data, by a first decoder of the signal analysis device;
a step of performing decoding processing on a signal including second floor noise, which is downconverted to a signal of an intermediate frequency by the second baseband converter, into IQ data, by a second decoder of the signal analysis device; and
a step of calculating error vectors from the IQ data of the first decoder and the IQ data of the second decoder, performing a cross correlation EVM calculation using the calculated error vectors, and performing average processing on results of the cross correlation EVM calculation to calculate a cross correlation EVM.

6. The wireless measurement method according to claim 5, further comprising:
a step of connecting a plurality of the down converters in series between the attenuator and the AD converter.

7. The wireless measurement method according to claim 5, further comprising:
a step of setting the number of samples, an input level range, and an input level measurement step of the transmission signal, as a first measurement condition;
a step of displaying a graph showing a relationship between the cross correlation EVM, which is calculated in a case where the first measurement condition is set, and the input level; and
a step of selecting an appropriate input level from the graph showing the relationship between the cross correlation EVM and the input level.

8. The wireless measurement method according to claim 7, further comprising:
a step of calculating a cross correlation EVM in a case where the input level, which is selected from the graph showing the relationship between the cross correlation EVM and the input level, and a range of the number of samples are set, as a second measurement condition;
a step of displaying a graph showing a relationship between the cross correlation EVM, which is calculated in a case where the second measurement condition is set, and the number of samples; and
a step of calculating a final EVM value from the graph showing the relationship between the cross correlation EVM and the number of samples.
